(19) United States
(12) Patent Application Publication
(10) Pub. No.: US 2016/0289833 A1
(43) Pub. Date: Oct. 6, 2016

(54) Vertical Heat Treatment Apparatus

(71) Applicant: TOKYO ELECTRON LIMITED, Tokyo (JP)

(72) Inventors: Mitsuhiro OKADA, Nirasaki City (JP); Katsuhiko KOMORI, Nirasaki City (JP)

(21) Appl. No.: 15/082,442

(22) Filed: Mar. 28, 2016

(30) Foreign Application Priority Data
Mar. 31, 2015 (JP) 2015-073099

(51) Int. Cl. C23C 16/455; H01L 21/67; C23C 16/46; C23C 16/44; C23C 16/458

(52) U.S. Cl. CPC C23C 16/45578; C23C 16/4412; C23C 16/4583; C23C 16/46; H01L 21/67109

(57) ABSTRACT

A vertical heat treatment apparatus includes a plurality of gas supply pipes installed in one of left-right-half regions of a reaction vessel and configured to supply a process gas to division regions obtained by dividing a processing region; an exhaust opening formed in a wall of the reaction vessel in the other of the left-right-half regions; and a vacuum exhaust path in communication with the exhaust opening. The plurality of gas supply pipes are installed to extend from an inner wall portion of the reaction vessel at a position lower than the processing region. At least one of the gas supply pipes includes a bent portion formed by bending downward a leading end portion that is extended upward, and a plurality of gas discharge holes are formed at a downstream side from the bent portion.

### CROSS-REFERENCE TO RELATED APPLICATION

This application claims the benefit of Japanese Patent Application No. 2015-073099, filed on Mar. 31, 2015, in the Japan Patent Office, the disclosure of which is incorporated herein in its entirety by reference.

### TECHNICAL FIELD

The present disclosure relates to a vertical heat treatment apparatus of performing a film forming process by supplying a process gas to a plurality of substrates held in a shelf fashion by a substrate holder inside a vertical reaction vessel surrounded by a heating part.

### BACKGROUND

In performing a film forming process by supplying a gas to semiconductor wafers (hereinafter, referred to as “wafers”) held in a shelf fashion by a wafer boat through gas discharge holes formed in a gas supply pipe along a longitudinal direction inside a reaction vessel of a vertical heat treatment apparatus, schemes for improving an in-plane uniformity of the film quality or film thickness is devised. As one of the above film forming schemes, a method of dividing a processing region into plural regions along an arrangement direction of wafers and supplying gas to the divided processing regions through different gas supply pipes, is employed.

Such a method is adapted to suppress a fluctuation in gas concentration in the arrangement direction (inter-plane direction) of the wafers, but in some cases, fails to ensure a high uniformity of the film thickness or film quality in the inter-plane direction. It is presumed that the reason for this failure is that the thermal decomposition of a gas is started in the gas supply pipes of the reaction vessel, the gas of which decomposition progresses is discharged as a gas supply path reaching to the gas discharge holes is lengthened, and as a result, a substantial uniformity of the gas concentration in the inter-plane direction is deteriorated.

For example, there is known a configuration in which a U-shaped first gas supply nozzle which is bent downward and a straight pipe-shaped second gas supply nozzle are provided inside a reaction vessel, in which an injection port of the first gas nozzle and an injection port of the second gas supply nozzle are formed opposite to each other at lower and upper sides of the wafer boat, respectively. In addition, a distance from an upstream end of the first gas supply nozzle to the most upstream injection port of the first gas supply nozzle is set to be equal to that from an upstream end of the second gas supply nozzle to the most upstream injection port of the first gas supply nozzle. However, since the reaction vessel is exhausted from below so that a gas flows downward from above, even though the supply amounts of the gas at upper and lower portions of the wafer boat are uniform, it is difficult to uniformalize the gas concentration in the inter-plane direction

### SUMMARY

Some embodiments of the present disclosure provide a technique which is capable of ensuring a high uniformity of a film forming process in an arrangement direction of substrates, in performing the film forming process by supplying a process gas to the plurality of substrates held in a shelf fashion by a substrate holder inside a vertical reaction vessel.

According to one embodiment of the present disclosure, there is provided a vertical heat treatment apparatus of performing a heat treatment by supplying process gases to a plurality of substrates, which are held in a shelf fashion by a substrate holder in a vertical reaction vessel that is surrounded by a heating part, the vertical heat treatment apparatus including: a plurality of gas supply pipes configured to supply the process gases to a plurality of division regions obtained by dividing a processing region, in which the substrates arranged in a longitudinal direction of the reaction vessel, the plurality of gas supply pipes being installed in one of a left-half region and a right-half region of the reaction vessel when viewed from the top of the reaction vessel; an exhaust opening formed in a wall of the reaction vessel in the other of the left-half region and the right-half region along the longitudinal direction; and a vacuum exhaust path in communication with the exhaust opening, wherein the plurality of gas supply pipes are installed to extend from an inner wall portion of the reaction vessel at a position lower than the processing region in which the substrates are arranged and to extend upward, and each of the plurality of gas supply pipes includes a plurality of gas discharge holes formed in the longitudinal direction at a height position corresponding to the respective division region, wherein at least one of the plurality of gas supply pipes includes a bent portion formed by bending downward a leading end portion that is extended upward, and the plurality of gas discharge holes are formed at a downstream side from the bent portion, and wherein, assuming that a length from a base end portion of a gas supply path positioned in the reaction vessel up to an upstream side of a gas discharge hole which is positioned at the most upstream side in an array of the plurality of gas discharge holes formed in a respective gas supply pipe is referred to as an travel distance, the travel distance of one of the gas supply pipes is set to fall within ±10% of the travel distance of the other gas supply pipes.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a longitudinal cross sectional view illustrating a vertical heat treatment apparatus according to a first embodiment of the present disclosure

FIG. 2 is a transverse cross sectional view illustrating the vertical heat treatment apparatus.

FIG. 3 is a perspective view illustrating gas supply pipes installed in the vertical heat treatment apparatus.

FIG. 4 is an explanatory view schematically illustrating the gas supply pipes and a wafer boat, which are installed in the vertical heat treatment apparatus.

FIG. 5 is a transverse cross sectional view illustrating a vertical heat treatment apparatus according to a second embodiment of the present disclosure.

FIG. 6 is a perspective view illustrating gas supply pipes installed in the vertical heat treatment apparatus.

FIG. 7 is a longitudinal cross sectional view illustrating another example of the vertical heat treatment apparatus of the present disclosure.

FIG. 8 is a longitudinal cross sectional view illustrating still another example of the vertical heat treatment apparatus of the present disclosure.

FIG. 9 is a characteristic view illustrating results of an evaluation test of the present disclosure.

FIG. 10 is an explanatory view illustrating results of an evaluation test of the present disclosure.

FIG. 11 is a characteristic view illustrating results of an evaluation test of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### First Embodiment

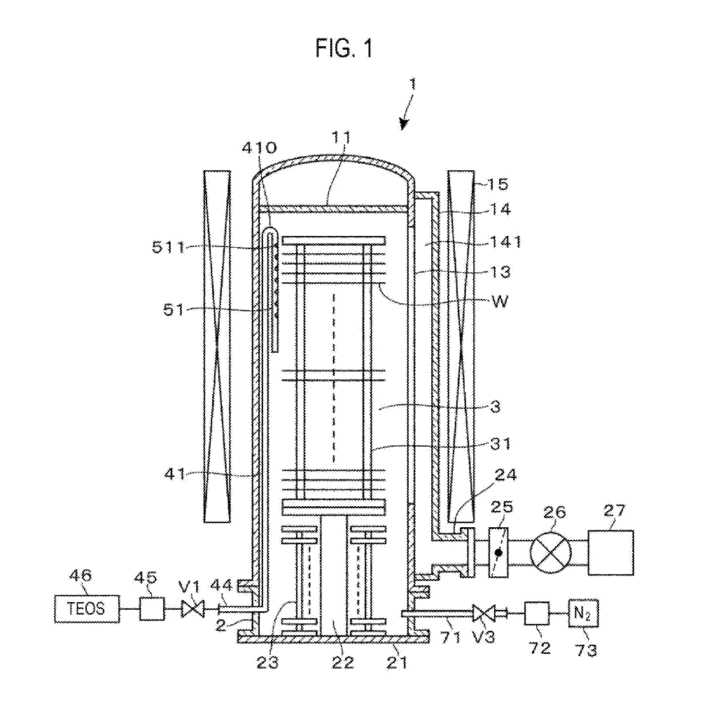

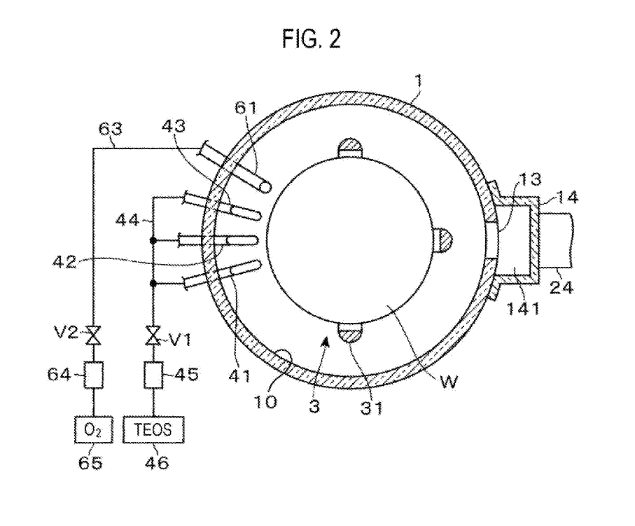

A first embodiment of a vertical heat treatment apparatus of the present disclosure will be described with reference to FIGS. 1 and 2. FIG. 1 is a longitudinal cross sectional view of the vertical heat treatment apparatus, and FIG. 2 is a transverse cross sectional view of the vertical heat treatment apparatus. In each of FIGS. 1 and 2, a reference numeral 1 designates a vertical cylinder reaction tube formed of, for example, quartz. An upper portion of the reaction tube 1 is sealed by a ceiling plate 11 made of quartz. In addition, a lower end of the reaction tube 1 is connected to a cylindrical manifold 2 formed of, for example, stainless steel, so that a combination of the reaction tube 1 and the manifold 2 constitutes a reaction vessel. A lower end of the manifold 2 is opened to function as a substrate loading/unloading port and is configured to be air-tightly closed by a quartz lid 21 which is installed in a boat elevator (not shown). A rotating shaft 22 is installed to penetrate through a central portion of the lid 21. A wafer boat 3 as a substrate holder is mounted on an upper end of the rotating shaft 22.

The wafer boat 3 includes, for example, three posts 31 which are configured to support a plurality of wafers W such that the wafer boat 3 supports outer periphery portions of the wafers W in a shelf fashion. The wafer boat 3 is configured to move up and down between a processing position at which the substrate loading/unloading port of the reaction tube 1 is closed by the lid 21 after the wafer boat 3 is loaded into the reaction tube 1 and an unloading position below the reaction tube 1. In addition, the wafer boat 3 is configured to rotate around a vertical axis through the rotating shaft 22 by a rotating mechanism (not shown). A reference numeral 23 in FIG. 1 designates an insulating unit.

A plurality of (e.g., three) gas supply pipes 41 to 43 is installed at a lateral side of the wafer boat 3 inside the reaction tube 1. These three gas supply pipes 41 to 43 are referred to as a first gas supply pipe 41, a second gas supply pipe 42, and a third gas supply pipe 43. Each of the first to third gas supply pipes 41 to 43 is configured as a quartz pipe having, e.g., a circular cross section. The first to third gas supply pipes 41 to 43 are installed in one of left-half and right-half regions as viewed from the top of the reaction tube 1. In this embodiment, the first to third gas supply pipes 41 to 43 are installed in the left-half region.

For example, a base end portion of each of the first to third gas supply pipes 41 to 43 is connected to an inner wall portion 10 of the manifold 2, and its leading end side is closed. In addition, as shown in FIGS. 1 to 3, each of the first to third gas supply pipes 41 to 43 is installed to extend horizontally inward of the inner wall portion 10 of the manifold 2 and extend vertically upward. Further, a leading end of the upwardly extended portion in the respective gas supply pipe is bent downward, followed by being extended vertically downward. In this embodiment, the first to third gas supply pipes 41 to 43 are installed to be bent inward of the reaction tube 1.

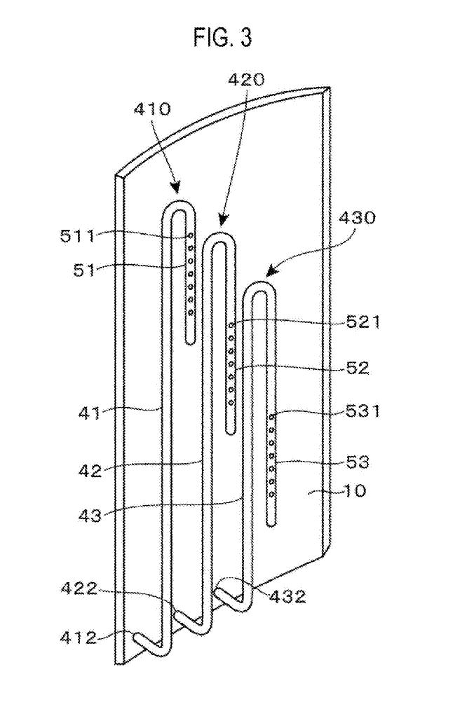

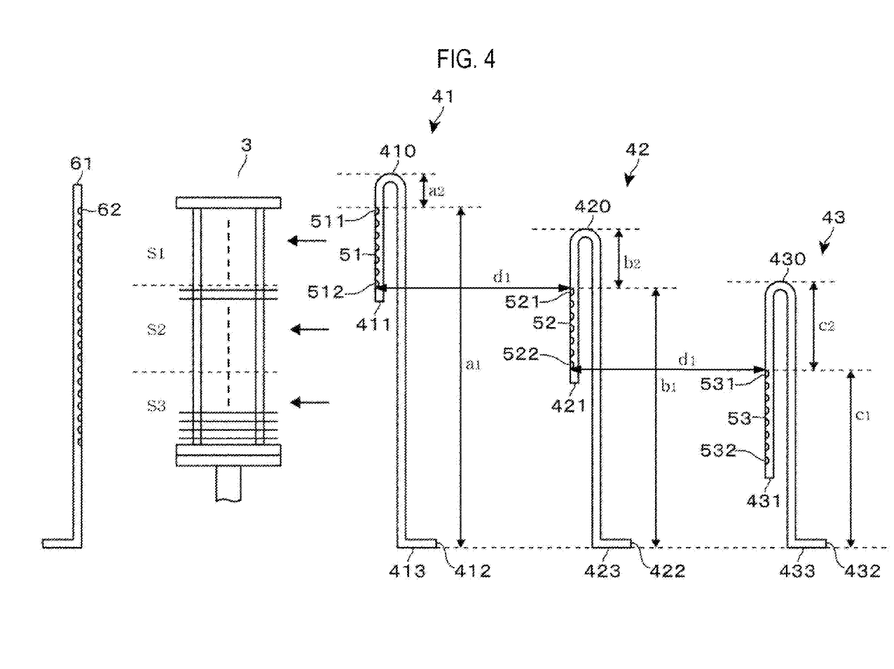

As shown in FIGS. 3 and 4, the first to third gas supply pipes 41 to 43 are installed such that portions at which the leading ends are bent (hereinafter, referred to as “bent portions”) 410, 420, and 430 are different in height from one another. FIG. 4 schematically illustrates a height relationship between the wafer boat 3 and the first to third gas supply pipes 41 to 43. As shown in FIG. 4, the first gas supply pipe 41 is bent at, e.g., a height position over a ceiling portion of the wafer boat 3. The third gas supply pipe 43 is bent at, e.g., a height position over a leading end portion 411 of the first gas supply pipe 41, and a leading end portion 431 of the third gas supply pipe 43 is positioned below the wafer boat 3. The second gas supply pipe 42 is bent at, e.g., a height position between the bent portions 410 and 430 of the first and third gas supply pipes 41 and 43, such that a leading end portion 421 of the second gas supply pipe 42 is positioned at a height position between the leading end portions 411 and 431 of the first and third gas supply pipes 41 and 43. The bent portions 410, 420, and 430 of the first to third gas supply pipes 41 to 43 are identical in shape to one another (see FIG. 4). Further, as shown in FIG. 2, the first and third gas supply pipes 41 and 43 are installed such that distances between downstream ends of the bent portions 410, 420 and 430 and outer peripheries of the wafers W held by the wafer boat 3 are identical to one another.

In the first to third gas supply pipes 41 to 43, the gas discharge holes 51, 52, and 53 are formed between the bent portions 410, 420, and 430 and the leading ends of the first to third gas supply pipes 41 to 43, respectively. Hereinafter, the gas discharge holes 51, 52, and 53 are sometimes referred to as first, second, and third gas discharge holes 51, 52, and 53, respectively. As described above, since the height positions of the bent portions 410, 420, and 430 are different from one another, height positions of the gas discharge holes 51, 52, and 53 in the first to third gas supply pipes 41 to 43 are different from one another. In this configuration, the gas discharge holes 51 to 53 of the first to third gas supply pipes 41 to 43 serve to supply process gases to a plurality of division regions obtained by dividing a processing region having the wafers W arranged in a longitudinal direction of the reaction tube 1. In this embodiment, the processing region is divided into three division regions, i.e., a first division region S1, a second division region S2, and a third division region S3 in sequence starting from the top.

In addition, the first to third gas discharge holes 51 to 53 are arranged such that the process gases are supplied to the first, second, and third division regions S1, S2, and S3 from the first, second, and third gas discharge holes 51, 52, and 53, respectively. The first to third gas discharge holes 51 to 53 are formed in circular shapes having the same size and are arranged at a regular arrangement pitch d0 along the longitudinal direction of the first to third gas supply pipes 41 to 43, respectively.

Here, in the first to third gas supply pipes 41 to 43 which constitute gas supply paths formed in the reaction tube 1, lengths from the base end portions of the gas supply pipes 41 to 43 up to upstream sides of the gas discharge holes 511, 521, and 531 which are respectively positioned at the uppermost sides in the arrays of the first to third gas discharge holes 51 to 53 are referred to as travel distances a1, b1 and c1, respectively. In other words, the travel distances correspond to lengths between connection ends 412, 422, and 432 of the gas supply pipes 41 to 43 with the manifold 2 and the gas discharge holes 511, 521, and 531, respectively. In addition, the travel distances of the first to third gas supply pipes 41 to 43 are set such that the travel distance of one of the gas supply pipes falls within ±10% of the travel distance of each of the other gas supply pipes. That is to say, a difference between the travel distance of one gas supply pipe and the travel distance of each of the other gas supply pipes is set to fall within ±10% of the travel distance of the one gas supply pipe. In this manner, differences between the travel distances of the first to third gas supply pipes 41 to 43 become uniform.

A gas discharge hole 512 positioned at the lowermost side in the array of the gas discharge holes 51 of the first gas supply pipe 41 and the gas discharge hole 521 positioned at the uppermost side in the array of the gas discharge holes 52 of the second gas supply pipe 42 are arranged such that the distance between the gas discharge hole 512 and the gas discharge hole 521 becomes d1. Similarly, a gas discharge hole 522 positioned at the lowermost side in the array of the gas discharge holes 52 of the second gas supply pipe 42 and the gas discharge hole 531 positioned at the uppermost side in the array of the gas discharge holes 53 of the third gas supply pipe 43 are arranged such that the distance between the gas discharge hole 522 and the gas discharge hole 531 becomes the distance d1. The distance d1 corresponds to a distance at which a difference between the distance d1 and the arrangement pitch d0 falls within ±10% of the arrangement pitch d0. With this configuration, in a case where the process gases are supplied to the first to third division regions S1 to S3 from the gas discharge holes 51 to 53 of the gas supply pipes 41 to 43 independently of one another, the gas discharge holes 51 to 53 are formed such that they are arranged at an approximately regular arrangement pitch with respect to the adjacent division regions S1 to S3. Thus, the gas discharge holes 51 to 53 are arranged at an approximately regular arrangement pitch in the longitudinal direction of the processing region.

As described above, the bent portions 410, 420, and 430 of the first to third gas supply pipes 41 to 43 have the same shape, and the portions 413, 423, and 433 extending horizontally from the inner wall portion 10 of the manifold 2 have the same length. Thus, the travel distance of the first gas supply pipe 41 is approximated as a1+2a2, the travel distance of the second gas supply pipe 42 is approximated as b1+2b2, and the travel distance of the third gas supply pipe 43 is approximated as c1+2c2. Further, for example, a difference between the distance a1+2a2 and the distance b1+2b2 is set to fall within ±10% of the distance a1+2a2, and a difference between the distance a1+2a2 and the distance c1+2c2 is set to fall within ±10% of the distance a1+2a2.

For example, the first to third gas discharge holes 51 to 53 are respectively arranged to discharge the process gases toward gaps between the wafers W held by the wafer boat 3 in a shelf fashion. Further, for example, distances between the first to third gas discharge holes 51 to 53 and the outer peripheries of the wafers W held by the wafer boat 3 are set to be uniform. In this embodiment, lengths between the gas discharge holes 512, 522, and 532 positioned at the lowermost sides in the arrays of the first to third gas discharge holes 51 to 53 and the respective leading end portions 411, 421 and 431 of the first to third gas supply pipes 41 to 43 are set to be uniform.

The overall configuration of the vertical heat treatment apparatus will be described again with reference to FIGS. 1 to 3. A cylindrical heater 15 as a heating part is installed to surround the outer circumference of the reaction tube 1. An oxidation gas supply pipe 61 configured to supply an oxidation gas (e.g., oxygen (O₂) gas) is connected to the manifold 2. The oxidation gas supply pipe 61 is configured as, for example, a quartz pipe having a circular cross section. For example, as shown in FIGS. 2 and 4, the oxidation gas supply pipe 61 is configured to horizontally penetrate into the inside of the reaction tube 1 from the manifold 2, bend vertically upward, and extend upward along the arrangement direction of the wafers W. A plurality of gas discharge holes 62 through which the oxidation gas is discharged toward the wafers W is formed in the oxidation gas supply pipe 61 at a predetermined interval along a longitudinal direction of the oxidation gas supply pipe 61. In addition, a replacement gas supply path 71 through which an inert gas (e.g., nitrogen (N₂) gas) as a replacement gas is supplied, is installed to penetrate into the manifold 2.

The first to third gas supply pipes 41 to 43 are coupled to a process gas supply path 44 through which a process gas (e.g., orthosilicate tetraethyl (TEOS) via the manifold 2. A leading end of the process gas supply path 44 is divided into a plurality of (e.g., three) branch lines to which the first to third gas supply pipes 41 to 43 are respectively connected. The process gas supply path 44 is coupled to a TEOS gas supply source 46 via a valve V1 and a flow rate control part 45. The oxidation gas supply pipe 61 is coupled to an O₂ gas supply source via an oxidation gas supply path 63 in which a valve V2 and a flow rate control part 64 are installed.

The replacement gas supply path 71 is coupled to an N₂ gas supply source 73 via a valve V3 and a flow rate control part 72. The valves V1 to V3 are to supply and stop the gases. The flow rate control parts 45, 64, and 72 are to adjust supply amounts of the gases. The TEOS, O₂, and N₂ gases are supplied at predetermined flow rates into the reaction tube 1 from the first to third gas supply pipes 41 to 43, the oxidation gas supply pipe 61, and the replacement gas supply path 71 at predetermined timings, respectively.

As shown in FIGS. 1 and 2, in one (in this embodiment, the right-half region) of the left-half region and the right-half region of the reaction tube 1 as viewed from the top of the reaction tube 1, a vertically elongated exhaust opening 13 through which an internal atmosphere of the reaction tube 1 is vacuum-exhausted, is formed in a wall of the reaction tube 1 along its longitudinal direction. The opening 13 is formed to face the region in which the wafers W are arranged in the wafer boat 3. Thus, the opening 13 is formed to face lateral sides of all of the wafers W.

In this manner, the first to third gas supply pipes 41 to 43 and the oxidation gas supply pipe 61 are installed at one of left and right sides of the wafers W inside the reaction tube 1, and the exhaust opening 13 is formed at the other of the left and right sides in the reaction tube 1. In addition, as shown in FIG. 2, for example, the second gas supply pipe 42 is disposed in a region opposite to the opening 13, and the first to third gas supply pipes 41 to 43 are connected to the inner wall portion 10 of the reaction tube 1 (or the manifold 2) along the circumferential direction of the reaction tube 1 (or the manifold 2), for example, at an regular interval.

An exhaust cover member 14 formed of, for example, quartz in the shape of a U-shaped cross section is installed to cover the opening 13. For example, the exhaust cover member 14 is formed in the wall of the reaction tube 1 along the longitudinal direction of the reaction tube 1. For example, one end of an exhaust pipe 24 is connected to a lower portion of the exhaust cover member 14. A region defined by the exhaust cover member 14 constitutes a vacuum exhaust path 141 which is in communication with the exhaust opening 13. The other end of the exhaust pipe 24 is connected to a vacuum pump 27 used as an exhaust mechanism through a pressure control part 25 equipped with a butterfly valve, and an on-off valve 26.

In this embodiment, the opening area of the opening 13 formed in the wall of the reaction tube 1 is set to be greater than a cross sectional area of the exhaust pipe 24. This is because the conductance is deteriorated and the controllability is lost if the opening area of the opening 13 is set to be excessively smaller than the cross sectional area of the exhaust pipe 24. However, if the opening area of the opening 13 is set to be excessively large, it is difficult for the exhaust gas uniformly flow. Hence, assuming that the opening area of the opening 13 is D1 and the cross sectional area of the exhaust pipe 24 is D2, the opening 13 and the exhaust pipe 24 may be configured such that 0.75≦D1/D≦21.25 is satisfied. As an example of dimensions of the opening 13 and the exhaust pipe 24, a width (size in the circumferential direction) of the opening 13 falls within a range of, e.g., 5 to 6 mm, a length of the opening 13 falls within a range of, e.g., 1300 to 1400 mm, and the cross sectional area of the exhaust pipe 24 is, e.g., 6077 mm² From these, the opening area of the opening 13 becomes 6150 mm² so that the condition 0.75≦D1/D≦21.25 is satisfied.

The vertical heat treatment apparatus configured as above is connected to a control part (not shown). The control part includes, for example, a computer equipped with a CPU and a memory part. The memory part stores a program organized with steps (commands) for controlling operations of the vertical heat treatment apparatus, in this embodiment, an operation when performing a film forming process on the wafers W inside the reaction tube 1. The program is stored in a storage medium such as a hard disk, a compact disk, a magneto-optical disk, a memory card or the like, and installed to the computer therefrom.

Next, an example of a film forming method performed in the vertical heat treatment apparatus of the present disclosure will be described. First, the wafer boat 3 having unprocessed wafers W mounted is loaded into the reaction tube 1. The interior of the reaction tube 1 is set to have a vacuum atmosphere of about 26.55 Pa by operating the vacuum pump 27. In addition, the wafers W are heated to a predetermined temperature, for example, 500 degrees C., by the heater 15. In a state where the wafer boat 3 is rotated, the valves V1 and V2 are opened.

Since the interior of the reaction tube 1 is set to have the vacuum atmosphere, if the valve V1 is opened, the TEOS gas flows into the first to third gas supply pipes 41 to 43 through the process gas supply path 44 and then is discharged toward the first to third division regions S1 to S3 through the first to third gas discharge holes 51 to 53, respectively. Also, if the valve V2 is opened, the O₂ gas is discharged into the reaction tube 1 through the oxidation gas supply path 63 and the oxidation gas supply tube 61. Subsequently, the TEOS gas and the O₂ gas flow toward the opening 13 inside the reaction tube 1. Since the first to third gas discharge holes 51 to 53 and the gas discharge holes 62 are opened toward the gaps between the wafers W vertically adjacent to etch other, the TEOS gas and the O₂ gas flow out from one to the other of the left and right sides over respective surfaces of the wafers W, so that molecules of TEOS and O₂ react with each other. Thus, a silicon oxide (SiO₂) film is formed on each of the wafers W.

Since the first to third gas supply pipes 41 to 43 are heated in the vacuum atmosphere, the TEOS gas starts to decompose inside the gas supply pipes 41 to 43. The decomposition amount (decomposition degree) of the TEOS gas depends on a period of time for which the TEOS gas flows through each of the gas supply pipes 41 to 43. Thus, the decomposition amount is increased as each of the gas supply pipes 41 to 43 is lengthened. On the other hand, in this embodiment, since the travel distances from the base end portions of the gas supply pipes 41 to 43 up to the gas discharge holes 511, 521, and 531 positioned respectively at the most upstream sides of the first to third gas supply pipes 41 to 43 are uniform, the process gases having the uniform decomposition amount are discharged from each of the gas discharge holes 511, 521, and 531.

In this way, the process gases having the uniform decomposition amount are discharged from the gas discharge holes 511, 521, and 531 positioned at the most upstream sides, which correspond to the respective first to third division regions S1 to S3. Since the arrangement pitches of the first to third gas discharge holes 51 to 53 are uniform, the process gases having the uniform decomposition amount are also discharged from the gas discharge holes positioned below the gas discharge holes 511, 521, and 531 in the first to third gas supply pipes 41 to 43. Thus, the decomposition amounts of the process gases in the arrangement direction (an inter-plane direction) of the wafers W between the first to third division regions S1 to S3 are uniform. In addition, the decomposition of the process gas does not occur inside the process gas supply path 44. Therefore, lengths of the process gas supply path 44 respectively connected to the first to third gas supply pipes 41 to 43 may be different.

After the SiO₂ film having a desired thickness is formed by performing the aforementioned film forming process for a predetermined period of time, the valves V1 and V2 are closed so that the supply of the gases from the first to third gas supply pipes 41 to 43 and the oxidation gas supply pipe 61 is stopped. Thereafter, the interiors of the reaction tube 1 and the manifold 2 are exhausted, and subsequently, the valve V3 is opened to supply the N₂ gas through the replacement gas supply path 71 so that the interior of the reaction tube 1 is purged. Thereafter, an internal pressure of the reaction tube 1 is returned to an atmospheric pressure, and subsequently, the wafer boat 3 is unloaded from the reaction tube 1. In this way, a series of film forming operations is completed.

In the above embodiment, the travel distances from the base end portions of the gas supply pipes 41 to 43 up to upstream sides of the gas discharge holes 511, 521, and 531 respectively positioned at the most upstream sides in the arrays of the first to third gas discharge holes 51 to 53 has been described to be set such that the travel distance of one of the gas supply pipes falls within ±10% of the travel distance of each of the other gas supply pipes, thus allowing the travel distances uniform. Accordingly, as described above, the process gases having the uniform decomposition amount are discharged from the gas discharge holes 511, 521, and 531 positioned at the most upstream sides and corresponding to the respective first to third division regions S1 to S3.

As described above, the exhaust opening 13 is formed in the wall of the reaction tube 1 along the longitudinal direction of the reaction tube 1 in the right-half region as viewed from the top of the reaction tube 1. Thus, the process gases supplied respectively to the first to third division regions S1 to S3 from the first to third gas supply pipes 41 to 43 flow out from one toward the other of the left and right sides of the reaction tube 1, so that the gases are suppressed from being mixed with each other in the vertical direction. Accordingly, the decomposition amounts of the process gases in the inter-plane direction between the first to third division regions S1 to S3 are uniform so that a fluctuation in the decomposition amount of the process gas in the inter-plane direction is suppressed as compared with when the process gas is supplied to the entire processing region from a single gas supply pipe. Even though the concentrations of the process gases are uniform, substantial gas concentrations may be fluctuated if the decomposition amounts of the process gases are different. However, in this embodiment, as described above, the decomposition amounts of the process gases in the inter-plane direction between the first to third division regions S1 to S3 are uniform so that a fluctuation in the substantial gas concentration is suppressed. Thus, the degree of the film forming process in the inter-plane direction between the first to third division regions S1 to S3 are uniform, which makes it possible to realize the film forming process having a high inter-plane uniformity.

For example, when the SiO₂ film is formed using the TEOS gas as the process gas, the film forming process is performed by the TEOS gases having the uniform decomposition amount in the inter-plane direction between the first to third division regions S1 to S3. Thus, shapes of thicknesses, or qualities such as surface roughnesses or contents of impurities, of films formed on the wafers W in the inter-plane direction become uniform, which makes it possible to ensure a uniform film thickness and a high inter-plane uniformity. In addition, as described above, the process gas flows from one toward the other of the left and right sides on the surface of each wafer W so that the process gas are evenly supplied on the surface of each wafer W. This results in good film thickness or good in-plane uniformity of film quality. Furthermore, since the shapes of the film thicknesses in the inter-plane direction become uniform, it is possible to easily perform an operation of adjusting a flow rate, pressure, or temperature of the process gas which is required to ensure a desired shape of the film thickness.

With the miniaturization of devices, surface areas of wafers W become enlarged. When a film forming process is performed on a wafer W having an enlarged surface area, the generation amount of by-products is increased, and a process gas is diluted by the generated by-products, thereby increasing a fluctuation in substantial gas concentration, in some cases. Even in this embodiment, the generation amount of by-products is increased when the film forming process is performed on such a wafer W having an enlarged surface area. However, since the process gases are supplied with the uniform decomposition amount in the inter-plane direction in the first to third division areas S1 to S3, the generation amounts of the by-products become uniform in the inter-plane direction. This substantially equalizes the degrees of dilution of the by-products in the inter-plane direction. In addition, since the process gas flows from one side toward the other side on the surface of the wafer W, the by-products are also discharged with the flow of the process gas. Hence, the degree of dilution is not fluctuated as the by-products move upward or downward while the process gas flows in the reaction tube 1. Thus, the uniformity of the film forming process in the inter-plane direction is ensured even when the process gas is diluted by the by-products.

In the above embodiment, as described above, the process gases are supplied from the first to third gas supply pipes 41 to 43 in a state where the decomposition amounts of the process gases between the first to third division regions S1 to S3 are uniform and the reaction tube 1 is exhausted from its lateral side, so that high in-plane uniformity and high inter-plane uniformity of the film forming process are ensured. For example, although the process gases having the uniform decomposition amount are supplied from the first to third gas supply pipes 41 to 43, in a configuration in which a reaction vessel is exhausted from an upper or lower portion of the first to third gas supply pipes 41 to 43, time periods required for the process gases to flow inside the reaction vessel are different in the inter-plane direction. This fluctuates a substantial gas concentration, which deteriorates the inter-plane uniformity of the film forming process. In addition, when the generation amount of by-products increases, the degrees of dilution by the by-products are different in the inter-plane direction as well as a fluctuation in the gas concentration, which further deteriorates the inter-plane uniformity. Furthermore, in a case where the surface area of the wafer W is enlarged and the generation amount of by-products increases, since the by-products move in the exhaust direction, the amount of dilution by the by-products increases, and the in-plane uniformity of the film thickness or film quality is also deteriorated.

In the above embodiment, the distances between the first to third gas discharge holes 51 to 53 and the outer peripheries of the wafers W held by the wafer boat 3 are uniform and the reaction tube 1 is exhausted from its lateral side. Thus, time periods for which the process gases discharged from the first to third gas discharge holes 51 to 53 reach the respective wafers W are uniform in the inter-plane direction, which contributes to improve the inter-plane uniformity.

### Second Embodiment

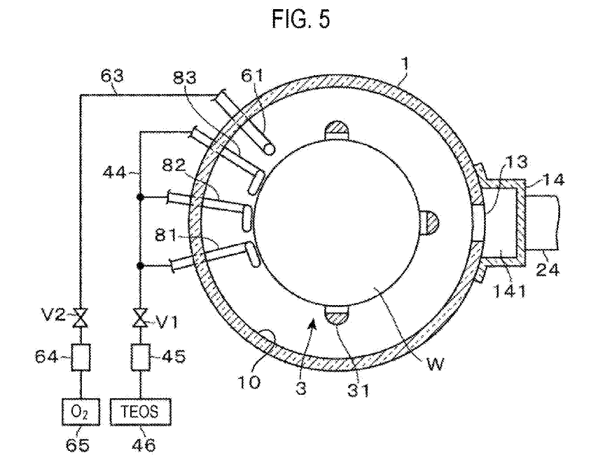

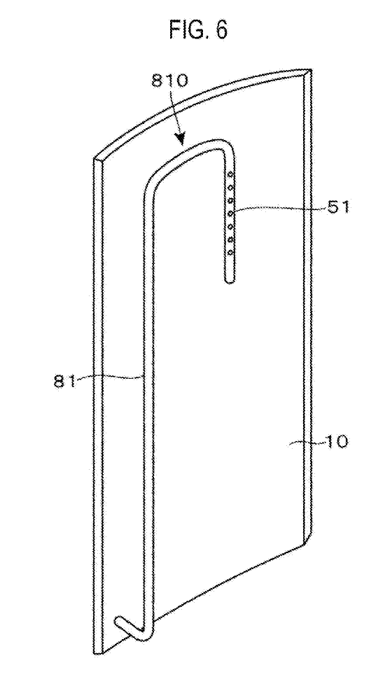

Next, a second embodiment of the present disclosure will be described with reference to FIGS. 5 and 6. This embodiment is different from the first embodiment in that first to third gas supply pipes 81 to 83 are installed to be bent along the wall of the reaction tube 1. The gas discharge holes 51, 52, and 53 through which the process gases are supplied toward the first to third division regions S1, S2, and S3 are formed at leading end sides of bent portions 810, 820 (not shown), and 830 (not shown) of the first to third gas supply pipes 81 to 83, respectively. For example, distances between the first to third gas supply pipes 81 to 83 and the outer peripheries of the wafers W held by the wafer boat 3 are uniform.

The first to third gas discharge holes 51 to 53 are formed in circular shapes having the same size and are arranged at a regular arrangement pitch d0. In addition, travel distances from the base end portions of the first to third gas supply pipes 81 to 83 up to the respective gas discharge holes positioned at the most upstream sides of the first to third gas supply pipes 81 to 83 are set such that the travel distance of one gas supply pipe falls within ±10% of the travel distance of each of the other gas supply pipes, thereby allowing the travel distances uniform. This embodiment is configured identically to the first embodiment except that the first to third gas supply pipes 81 to 83 are installed to be bent along the wall of the reaction tube 1 as described above. Therefore, like components are designated by like reference numerals, and their descriptions will be omitted.

In the second embodiment, the process gases are supplied in a state where the decomposition amounts of the process gases between the first to third gas supply pipes 81 and 83 are uniform, and the reaction tube 1 is exhausted from the opening 13 formed in the wall of the reaction tube 1. This ensures an inter-plane uniformity and an in-plane uniformity of the film forming process. Furthermore, as shown in FIG. 5, the first to third gas supply pipes 81 to 83 are bent along the inner wall portion 10 of the reaction tube 1, so that the first to third gas supply pipes 81 to 83 and the wafer boat 3 can be approached to each other, thereby quickly supplying the process gases to the wafers W.

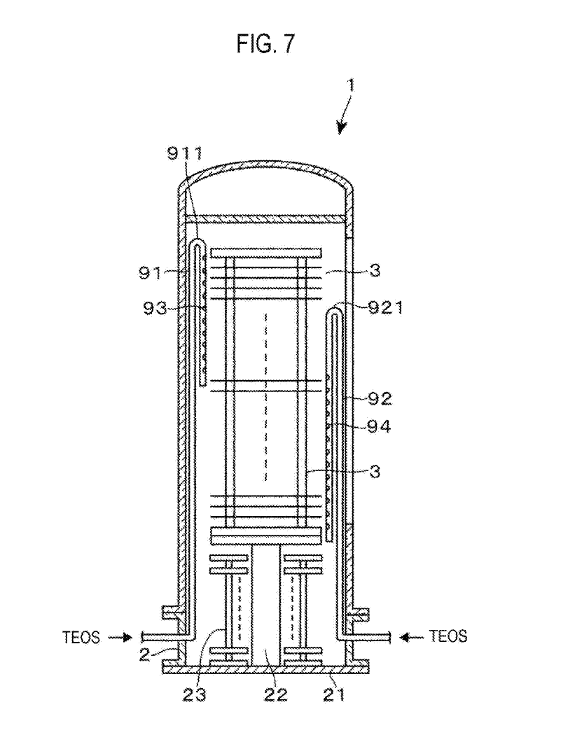

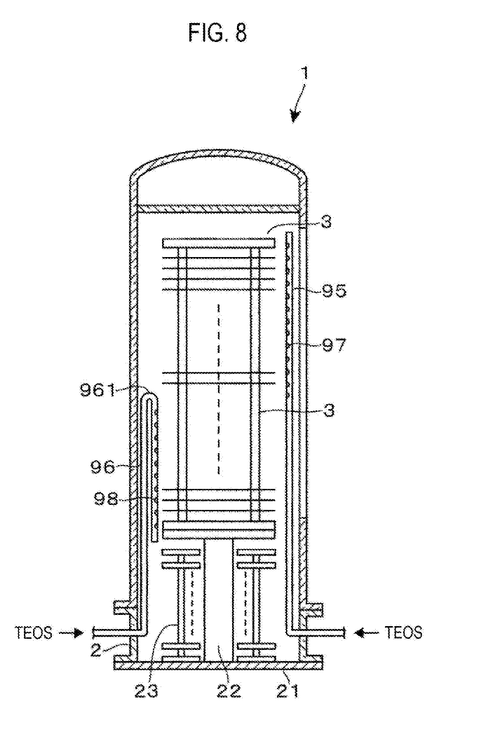

In some embodiments, as shown in FIGS. 7 and 8, two gas supply pipes may be used. In FIGS. 7 and 8, for convenience of illustration, two gas supply pipes are shown at left and right sides of the wafer boat 3, respectively. However, in practice, as shown in FIG. 1, both the two gas supply pipes are installed in one of a left-half region and a right-half region as viewed from the top of the reaction tube 1. FIG. 7 shows a configuration in which both of a gas supply pipe 91 that covers an upper division region and a gas supply pipe 92 that covers a lower division region are bent, and gas discharge holes 93 and 94 are formed at regular arrangement pitch in leading end sides of bent portions 911 and 921 of the gas supply pipes 91 and 92, respectively. In addition, travel distances from base end portions of the gas supply pipes 91 and 92 up to the respective gas discharge holes positioned at the most upstream sides of the gas supply pipes 91 and 92 are set such that the travel distance of one gas supply pipe (e.g., the gas supply pipe 92) falls within ±10% of the travel distance of the other gas supply pipe (e.g., the gas supply pipe 91), thus allowing the travel distances uniform. Assuming that a distance in a height direction between a gas discharge hole positioned at the lowermost side in the array of the gas discharge holes 93 of the gas supply pipe 91 and a gas discharge hole positioned at the uppermost side in the array of the gas discharge holes 94 of the gas supply pipe 92 is d1, and an arrangement pitch is d0, a difference between the distance dl and the arrangement pitch d0 is set to fall within ±10% of the arrangement pitch d0. The other configurations of this embodiment are similar to those of the first embodiment. According to such a configuration, it is possible to ensure an inter-plane uniformity and an in-plane uniformity of the film forming process.

FIG. 8 shows a configuration in which a gas supply pipe 95 that covers an upper division region vertically extends and a gas supply pipe 96 that covers a lower division region is bent. Gas discharge holes 97 and 98 are formed at a regular arrangement pitch in leading end sides of the gas supply pipe 95 and a bent portion 961 of the gas supply pipe 96, respectively. In addition, travel distances from base end portions of the gas supply pipes 95 and 96 up to the respective gas discharge holes positioned at the most upstream sides of the gas supply pipes 95 and 96 are set such that the travel distance of one gas supply pipe (e.g., the gas supply pipe 96) falls within ±10% of the travel distance of the other gas supply pipe (e.g., the gas supply pipe 95), thus allowing the travel distances uniform. Assuming that a distance in the height direction between a gas discharge hole positioned at the lowermost side in the array of the gas discharge holes 97 of the gas supply pipe 95 and a gas discharge hole positioned at the uppermost side in the array of the gas discharge holes 98 of the gas supply pipe 96 is d1 and an arrangement pitch is d0, a difference between the distance d1 and the arrangement pitch d0 is set to fall within ±10% of the arrangement pitch d0. The other configurations of this embodiment are similar to those of the first embodiment. According to such a configuration, it is possible to ensure an inter-plane uniformity and an in-plane uniformity of the film forming process. Although an example in which two gas supply pipes are used is shown in FIGS. 7 and 8, four or more gas supply pipes may be used in some embodiments. Further, in some embodiments, at least one of the gas supply pipes may be installed to have a bent portion.

Further, a communication structure or connection position between the gas supply pipes and an external process gas supply path (gas pipe) is not limited to the above-described configurations. In addition, the present disclosure may be applied in performing a heat treatment by supplying a process gas to a plurality of substrates held in a shelf fashion by a substrate holder in a vertical reaction vessel surrounded by a heating part, and may be applied to an etching process or the like, in addition to the film forming process. In addition to a film forming process using a chemical vapor deposition (CVD), the present disclosure may be applied to a film forming process using a so-called atomic layer deposition (ALD). Examples of the film forming process to which the present disclosure is applicable may include a process of forming a silicon nitride film through the CVD that uses a dichlorosilane gas, a hexachlorodisilane (HCD), or a bistertiarybutylaminosilane (BTBAS) gas as a process gas, and uses an ammonia gas as a nitriding gas, a process of forming a polysilicon film using a monosilane gas as a process gas, a process of forming an amorphous silicon film using a disilane gas as a process gas, and the like.

### EVALUATION EXAMPLE 1

Next, an evaluation test of the above-described vertical heat treatment apparatus will be described. By using the above-described vertical heat treatment apparatus of the first embodiment, a monosilane (SiH₄) gas as a process gas was supplied to 156 sheets of wafers W loaded into the wafer boat 3 at a flow rate of 1,500 sccm for a predetermined period of time to form a polysilicon film on each of the wafers W. At this time, a process pressure was set to 59.85 Pa (0.45 Torr), and a process temperature was set to 530 degrees C. Film thicknesses, in-plane uniformities, surface roughnesses, and shapes of the film thicknesses of the formed polysilicon films were evaluated (Example 1). In addition, as a comparative example, the same evaluation was performed using a vertical heat treatment apparatus having a configuration in which a reaction vessel is exhausted from a lower portion of the reaction vessel. An average value of film thicknesses measured at 49 points in a surface of a wafer to be evaluated was used as the film thickness, and an in-plane uniformity was calculated based on the average value and data of the film thicknesses measured at the 49 points (Comparative example 1). In addition, the surface roughnesses (Haze) were evaluated using a surface inspection apparatus (SP1 DLS manufactured by KLA-Tencor Corporation), and the shapes of the film thicknesses were evaluated using a film thickness meter (SFX200 manufactured by KLA-Tencor Corporation).

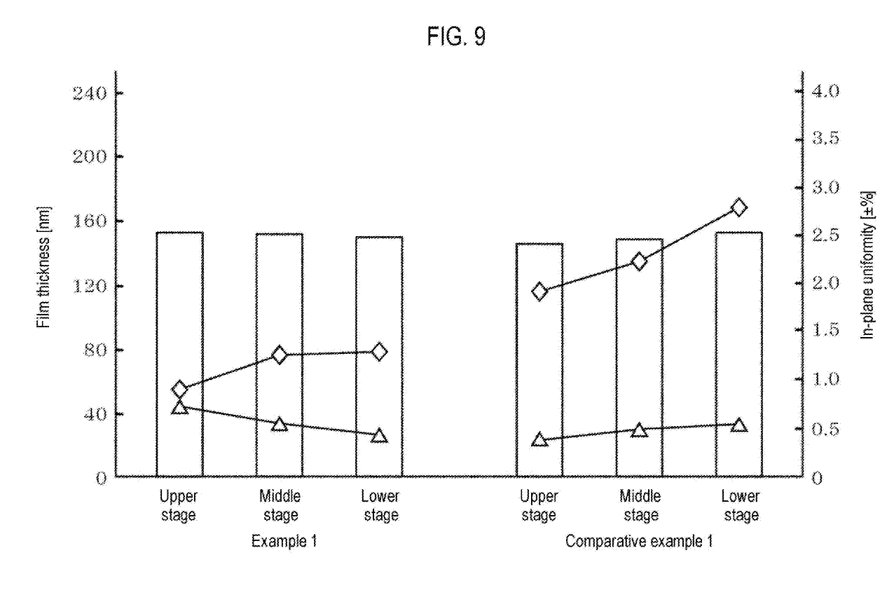

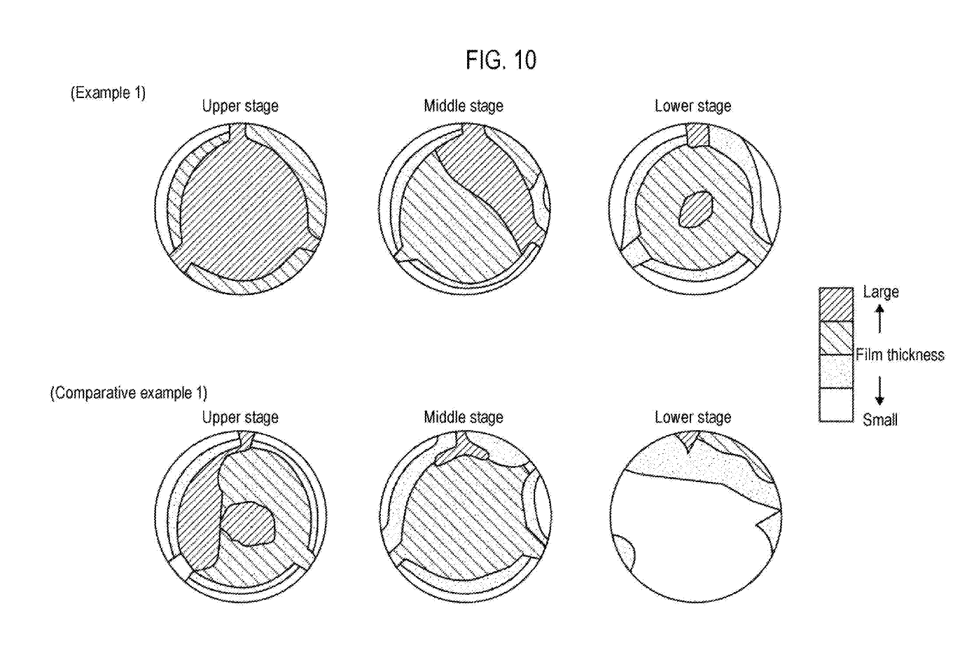

In terms of the results, the film thicknesses, the in-plane uniformities, and the surface roughnesses are shown in FIG. 9, and the shapes of the film thicknesses are shown in FIG. 10. In FIG. 9, results of Example 1 and Comparative example 1 are shown at left and right sides, respectively. Data of upper, middle, and lower stages of the wafer boat 3 are shown using bar graphs for the film thicknesses, plots of a symbol A for the in-plane uniformities, and plots of a symbol ⋄ for the surface roughnesses. In addition, the shapes of the film thicknesses are shown by tracing the data of the upper, middle, and lower stages of the wafer boat 3. The upper stage refers to the uppermost wafer (first wafer) W among the wafers W mounted in the wafer boat 3, the middle stage refers to a 51th wafer W starting from the top among the wafers W mounted in the wafer boat 3, and the lower stage refers to a 102th wafer W starting from the top among the wafers W mounted in the wafer boat 3.

As can be seen from FIG. 9, Example 1 shows good results as compared with Comparative example 1 in that the film thicknesses of the upper, middle, and lower stages of the wafer boat 3 are constant, the in-plane uniformities are good, and uniformity of the surface roughnesses in the inter-plane direction is also improved. In addition, as can be seen from FIG. 10, when representing the film thickness in four levels, Example 1 shows that all of the upper, middle, and lower stages of the wafer boat 3 had large film thicknesses as compared with Comparative example 1. Comparative example 1 shows that the film thickness in the lower stage is considerably smaller than the film thickness in the upper stage, and Example 1 shows that the in-plane uniformity of the shapes of the film thicknesses is high as compared with Comparative Example 1. Accordingly, as can be seen in Example 1, the process gases having an uniform decomposition amount are supplied from the first to third gas supply pipes 41 to 43 while exhausting the reaction tube 1 from a lateral side of the reaction tube 1, so that the inter-plane uniformity and in-plane uniformity of the film thicknesses and the film qualities (surface roughnesses) were remarkably improved as compared with the configuration of Comparative Example 1 in which the reaction tube 1 is exhausted from a lower portion of the reaction tube 1.

### EVALUATION EXAMPLE 2

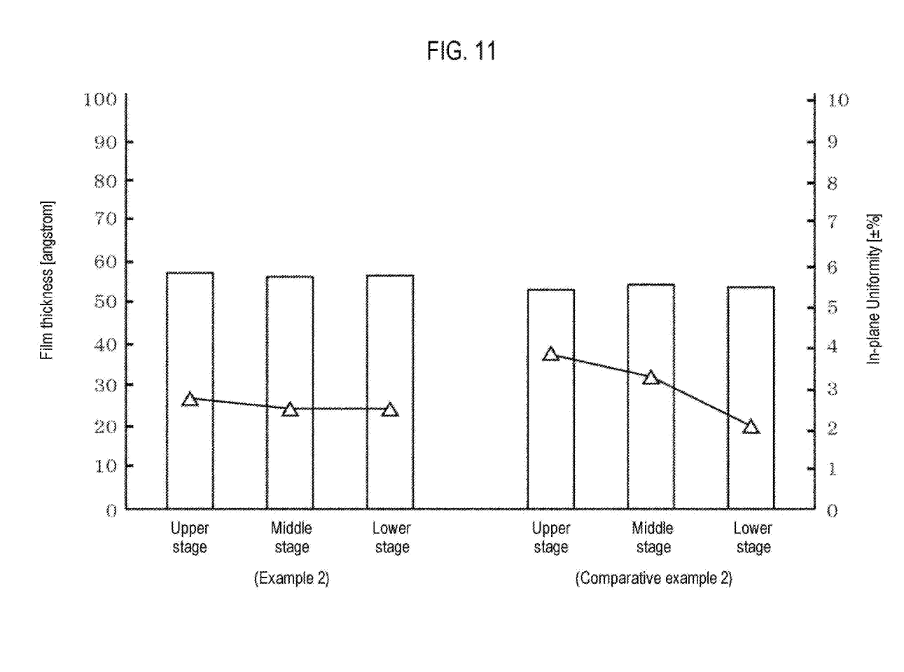

Further, an evaluation was performed for film thicknesses and in-plane uniformities of the film thicknesses in a case where an amorphous silicon film is formed on each wafer W by supplying a disilane (Si₂H₆) gas as the process gas at a flow rate of 350 sccm (Example 2). In addition, as a comparative example, the same evaluation was performed using a vertical heat treatment apparatus having a configuration in which a reaction vessel is exhausted from a lower portion of the reaction vessel (Comparative example 2). At this time, a process pressure was set to 133 Pa (1 Torr), and a process temperature was set to 380 degrees C. An evaluation method is the same as Evaluation example 1. The results are shown in FIG. 11.

In FIG. 11, results of Example 2 and Comparative example 2 are shown at left and right sides, respectively. Data of upper, middle, and lower stages of the wafer boat 3 are shown using bar graphs for the film thicknesses and plots of a symbol A for the in-plane uniformities. The upper, middle, and lower stages are defined similarly to those in Example 1. In terms of the results, Example 2 shows that fluctuations in film thicknesses between the upper, middle, and lower stages are small and in-plane uniformities are high, as compared with Comparative example 2, so that a high inter-plane uniformity and in-plane uniformity of a film forming process is achieved. Conventionally, in a film forming process using Si₂H₆ gas, it was required to perform adjustment of an in-plane film thickness distribution using a substrate holder in which ring-shaped mounting tables are disposed in multi-stages. However, according to the present disclosure, it is possible to perform such an adjustment using the wafer boat having the configuration shown in FIG. 1. The reason for this is that the in-plane uniformities of the film thicknesses are remarkably improved by supplying the process gases having the uniform decomposition amount from the first to third gas supply pipes 41 to 43 while exhausting the reaction tube 1 from the lateral side of the first to third gas supply pipes 41 to 43.

According to the present disclosure, a plurality of gas supply pipes which is configured to supply process gases to a plurality of division regions obtained by dividing a processing region having substrates arranged in a longitudinal direction of a reaction vessel, is installed in one of a left-half region and a right-half region as viewed from the top of the reaction vessel, and an exhaust opening is formed in the other of the left-half region and the right-half region. In addition, assuming that a length from a base end portion of a gas supply path positioned in the reaction vessel up to an upstream side of a gas discharge hole which is positioned at the most upstream side in an array of the gas discharge holes formed in a respective gas supply pipe is referred to as an travel distance, the travel distance of one of the gas supply pipes is set to fall within ±10% of the travel distance of each of the other gas supply pipes so that the travel distances are uniform. If the process gases reach the gas supply paths in the reaction vessel, thermal decomposition is started. Since the travel distances are uniform, the process gases having a uniform decomposition amount are supplied to each of the division regions from the gas discharge holes positioned at the most upstream sides of the plurality of gas supply pipes, followed by flowing out toward an exhaust opening in a transverse direction. Thus, degrees of film forming processes for the respective substrates in the arrangement direction are uniform between the division regions, which makes it possible to ensure a high uniformity of the film forming process in the arrangement direction.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A vertical heat treatment apparatus of performing a heat treatment by supplying process gases to a plurality of substrates, which are held in a shelf fashion by a substrate holder in a vertical reaction vessel that is surrounded by a heating part, the vertical heat treatment apparatus comprising:
a plurality of gas supply pipes configured to supply the process gases to a plurality of division regions obtained by dividing a processing region, in which the substrates arranged in a longitudinal direction of the reaction vessel, the plurality of gas supply pipes being installed in one of a left-half region and a right-half region of the reaction vessel when viewed from the top of the reaction vessel;
an exhaust opening formed in a wall of the reaction vessel in the other of the left-half region and the right-half region along the longitudinal direction; and
a vacuum exhaust path in communication with the exhaust opening,
wherein the plurality of gas supply pipes are installed to extend from an inner wall portion of the reaction vessel at a position lower than the processing region in which the substrates are arranged and to extend upward, and each of the plurality of gas supply pipes includes a plurality of gas discharge holes formed in the longitudinal direction at a height position corresponding to the respective division region,
wherein at least one of the plurality of gas supply pipes includes a bent portion formed by bending downward a leading end portion that is extended upward, and the plurality of gas discharge holes are formed at a downstream side from the bent portion, and
wherein, assuming that a length from a base end portion of a gas supply path positioned in the reaction vessel up to an upstream side of a gas discharge hole which is positioned at the most upstream side in an array of the plurality of gas discharge holes formed in a respective gas supply pipe is referred to as an travel distance, the travel distance of one of the gas supply pipes is set to fall within ±10% of the travel distance of the other gas supply pipes.

2. The vertical heat treatment apparatus of claim 1, wherein arrangement pitches of the plurality of gas discharge holes formed in the plurality of gas supply pipes corresponding to the processing region are all set to the same dimension, and
wherein, assuming that a distance in the height direction between a gas discharge hole positioned at the lowermost side in the array of the plurality of gas discharge holes of the gas supply pipe that covers an upper division region among the division regions adjacent to each other, and a gas discharge hole positioned at the uppermost side in the array of the plurality of gas discharge holes of the gas supply pipe that covers a lower division region among the division regions is d1, and the arrangement pitch is d0, a difference between the distance d1 and the arrangement pitch d0 is set to fall within ±10% of the arrangement pitch d0.

3. The vertical heat treatment apparatus of claim 1, wherein each of the plurality of gas supply pipes includes a bent portion formed by bending downward a leading end portion that is extended upward, and the plurality of gas discharge holes are formed at a downstream side from the bent portion.

4. The vertical heat treatment apparatus of claim 1, wherein the vacuum exhaust path in communication with the exhaust opening extends to a lower side along the reaction vessel and is connected to an exhaust pipe at the lower side, and
wherein the opening area of the exhaust opening is larger than a cross sectional area of the exhaust pipe.
